(19) United States
(12) Patent Application Publication
(10) Pub. No.: US 2022/0322519 A1
(43) Pub. Date: Oct. 6, 2022

(54) BOARD AND CIRCUIT BOARD

(71) Applicant: Skiileux Electricity Inc., Taoyuan City (TW)

(72) Inventors: Shang-Wei Tsai, Taoyuan City (TW); Cheng Chieh Chang, Taoyuan City (TW); Te Fu Chang, Taoyuan City (TW)

(73) Assignee: Skiileux Electricity Inc., Taoyuan City (TW)

(21) Appl. No.: 17/541,285

(22) Filed: Dec. 3, 2021

(30) Foreign Application Priority Data
Apr. 1, 2021 (TW) 110112224

(51) Int. Cl. H05K 1/02; F21V 29/90

(52) U.S. Cl. CPC H05K 1/0212; F21V 29/90; H05K 2201/10106; H05K 2201/10128; F21Y 2115/10

(57) ABSTRACT

A board, including a pad layer, a micro heater layer, and an insulating layer which are laminated, is provided. The pad layer includes a pad. The micro heater layer includes a micro heater. The micro heater is disposed corresponding to the pad. The insulating layer is located between the pad layer and the micro heater layer. A resistance value of the micro heater ranges from 10 Ω to 500 Ω. A circuit board is also provided.

### CROSS-REFERENCE TO RELATED APPLICATION

This application claims the priority benefit of Taiwan application serial no. 110112224, filed on Apr. 1, 2021. The entirety of the above-mentioned patent application is hereby incorporated by reference herein and made a part of this specification.

### BACKGROUND

### Technical Field

The disclosure relates to a board and a circuit board, and particularly relates to a board with a micro heater and a circuit board with a micro heater.

### Description of Related Art

If an element is to be connected onto a pad of a board, a solder member in the element is often soldered to the pad of the board through heating by a heat gun. However, such manner is more troublesome. In addition, the heating range of the heat gun is relatively large, which is difficult to locally heat a specific small area.

### SUMMARY

The disclosure provides a board and a circuit board, which are simpler to use or have better performance and/or applicability.

The board of the disclosure includes a pad layer, a micro heater layer, and an insulating layer which are laminated. The pad layer includes a pad. The micro heater layer includes a micro heater. The micro heater is disposed corresponding to the pad. The insulating layer is located between the pad layer and the micro heater layer. A resistance value of the micro heater ranges from 10Ω to 500Ω.

The circuit board of the disclosure includes the board and an electronic element. The board further includes a circuit layer electrically connected to the pad. The electronic element is electrically connected onto the pad.

Based on the above, through the micro heater of the board, the board/the circuit board can be simpler to use or have better performance and/or applicability.

### BRIEF DESCRIPTION OF THE DRAWINGS

FIG. 1A is a schematic partial cross-sectional view of a board or a circuit board according to an embodiment of the disclosure.

FIG. 1B is a schematic top view of a board or a circuit board according to an embodiment of the disclosure.

FIG. 2 is a schematic partial top view of a board or a circuit board according to an embodiment of the disclosure.

FIG. 3 is a schematic partial top view of a board or a circuit board according to an embodiment of the disclosure.

FIG. 4 is a schematic partial top view of a board or a circuit board according to an embodiment of the disclosure.

FIG. 5 is a schematic partial top view of a board or a circuit board according to an embodiment of the disclosure.

FIG. 6 is a schematic partial top view of a board or a circuit board according to an embodiment of the disclosure.

FIG. 7 is a schematic partial top view of a board or a circuit board according to an embodiment of the disclosure.

### DETAILED DESCRIPTION OF DISCLOSED EMBODIMENTS

The content of the following embodiments is for illustration rather than limitation. Moreover, the description of conventional devices, methods, and materials may be omitted, so as not to obscure the description of the various principles of the disclosure. Directional terms (such as up and down) used herein are only used with reference to the drawings or corresponding idioms and are not intended to imply absolute orientation. In the drawings, for the sake of clarity, sizes of some elements or film layers may be enlarged or reduced. It will be obvious to persons skilled in the art of the disclosure that the disclosure may be practiced in other embodiments that deviate from the specific details disclosed herein through the content of the embodiments and the corresponding illustration of the drawings.

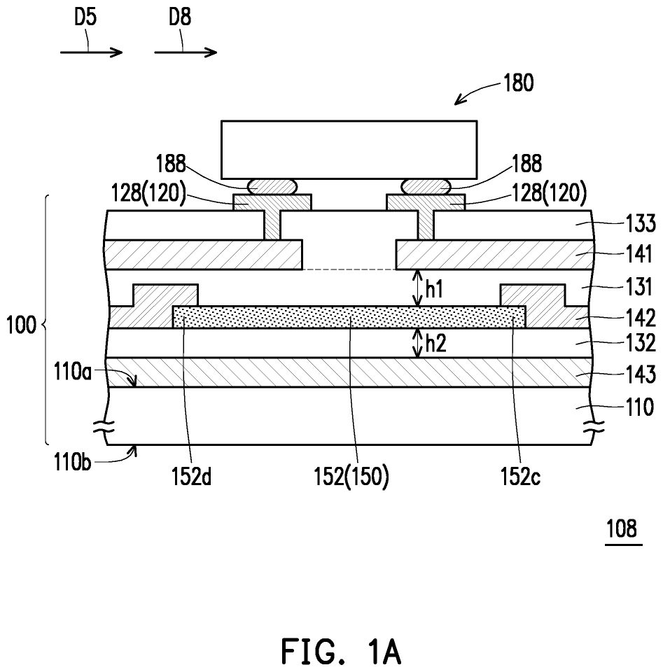

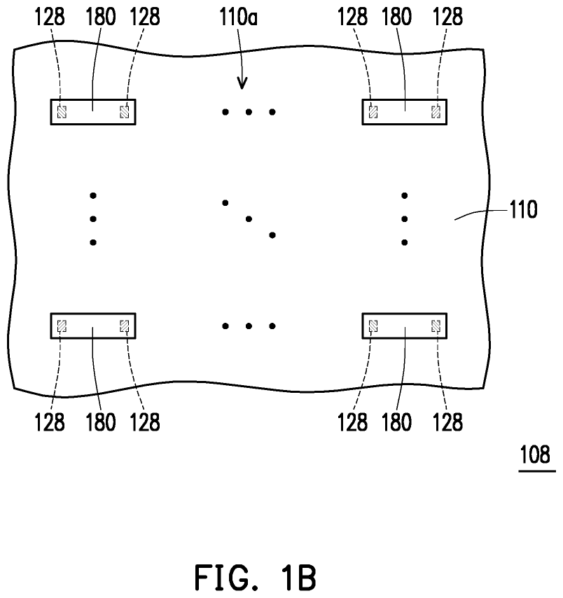

Please refer to FIG. 1A and FIG. 1B. A board 100 includes a pad layer 120, a micro heater layer 150, and a first insulating layer 131. The pad layer 120, the micro heater layer 150, and the first insulating layer 131 may be laminated on a first surface 110a of the board 110. The board 110 may include a rigid board (such as, but not limited to, a glass board and a glass fiber board (such as an FR4 board)) and/or a soft board (such as, but not limited to, a polyimide (PI) film or other suitable soft boards), but the disclosure is not limited thereto. In addition, in an embodiment not shown, there may also be other suitable film layers on a second surface 110b (that is, a surface opposite to the first surface 110a) of the board 110.

The pad layer 120 may include a pad 128. An element (such as, but not limited to, an electronic element 180 described later) may be disposed on the pad 128.

The micro heater layer 150 includes a micro heater 152. The micro heater 152 is disposed corresponding to the pad 128. The number and/or configuration of the micro heater 152 and/or the pad 128 may be adjusted according to design requirements, which are not limited in the disclosure. In the embodiment, one micro heater 152 may be disposed corresponding to two pads 128.

The resistance value of the micro heater 152 may range from 10 ohms (Ω) to 500Ω. In other words, the micro heater 152 may be a resistive heater.

The first insulating layer 131 is located between the pad layer 120 and the micro heater layer 150. The thermal conductivity of the first insulating layer 131 may range from 1 W·m⁻¹·K⁻¹ (W/m·K) to 700 W·m⁻¹·K⁻¹. Preferably, the thermal conductivity of the first insulating layer 131 may range from 1.5 W·m⁻¹·K⁻¹ to 490 W·m⁻¹·K⁻¹.

In the embodiment, the board 100 may further include a first circuit layer 141. The first insulating layer 131 may be located between the first circuit layer 141 and the micro heater layer 150. The layout design of the first circuit layer 141 may be adjusted according to requirements, which is not limited in the disclosure. A corresponding line in the first circuit layer 141 may be electrically connected to the pad 128.

In the embodiment, the board 100 may further include a second circuit layer 142. The layout design of the second circuit layer 142 may be adjusted according to requirements, which is not limited in the disclosure. A corresponding line in the second circuit layer 142 may be electrically connected to an end 152c of the micro heater 152, and another corresponding line in the second circuit layer 142 may be electrically connected to another end 152d of the micro heater 152. In other words, through the two ends 152c and 152d of the micro heater 152 electrically connected to the corresponding lines in the second circuit layer 142, a flow direction D5 of one of the current or the electron flow flowing through the micro heater 152 may be determined when heating by the micro heater 152.

In the embodiment, the board 100 may further include a second insulating layer 132. The micro heater layer 150 may be located between the second insulating layer 132 and the first insulating layer 131. The thermal conductivity of the second insulating layer 132 may range from 1.5 W·m⁻¹·K⁻¹ to 700 W·m⁻¹·K⁻¹. It should be noted that the disclosure does not limit the relationship between the thermal conductivity of the first insulating layer 131 and the thermal conductivity of the second insulating layer 132.

In the embodiment, the board 100 may further include a third circuit layer 143. The second insulating layer 132 may be located between the third circuit layer 143 and the micro heater layer 150. The layout design of the third circuit layer 143 may be adjusted according to requirements, which is not limited in the disclosure. For example, in an area not shown in FIG. 1A or in an embodiment not shown, a corresponding line in the third circuit layer 143 may be electrically connected to the corresponding pad 128 through a conductive via penetrating the first insulating layer 131 and/or the second insulating layer 132 and a corresponding line in the first circuit layer 141.

In the embodiment, the board 100 may further include a third insulating layer 133. The third insulating layer 133 may be an insulating layer farthest from the board 110 on the first surface 110a. Therefore, the third insulating layer 133 may be referred to as a protective layer or a solder resist layer.

In an exemplary application of the board 100, an element (such as, but not limited to, the electronic element 180 described later) may be disposed on the pad 128. The element may include a connector (such as, but not limited to, a conductive connector 188 described later) with a low melting point (that is, for example, less than the melting point of the pad layer 120, the micro heater layer 150, and the first insulating layer 131). Then, electric heating may be performed through the micro heater 152, and the thermal energy generated by the micro heater 152 may be transferred to the pad 128 and the connector thermally coupled thereon. In other words, the pad 128 and the connector located thereon may be heated by the micro heater 152. After moderate and/or timely heating, the connector thermally coupled to the pad 128 may be, for example, melted, so that there may be a good connection between the electronic element and the corresponding pad 128. Therefore, the board 100 can be simpler to use.

In an embodiment, the resistance value of the micro heater 152 may be less than or equal to 150Ω. For example, if the resistance value is greater than 150Ω, the driving voltage may need to be increased when the micro heater 152 performs electric heating, so as to correspondingly generate more thermal current. As a result, power consumption may be excessive and/or the complexity of a driving controller may be increased.

In an embodiment, the resistance value of the micro heater 152 may be greater than or equal to 40Ω. For example, the micro heater 152 needs to be electrically connected to other lines (such as a corresponding line in the second circuit layer 142), so that the micro heater 152 may perform electrical heating. Therefore, if the resistance value is less than 40Ω, the resistance value of the micro heater 152 may be too close to the resistance value of the line connected thereto (that is, the micro heater 152), and the line connected thereto may also be heated more than expected. As a result, other elements (such as lines connected to the micro heater 152) may be damaged or impaired, and there may also be difficulty in the design of the micro heater 152.

In an embodiment, the resistance value of the micro heater 152 may range from 40Ω to 150Ω. In this way, when the micro heater 152 performs electric heating, the amount of electricity used may be reduced and/or the damage or impairment of other elements may be reduced. Moreover, the design of the driving controller may also be simpler.

In the embodiment, a thickness h1 of the first insulating layer 131, the thermal conductivity of the first insulating layer 131, a thickness h2 of the second insulating layer 132, and the thermal conductivity of the second insulating layer 132 have the following relationship: (the thermal conductivity of the first insulating layer 131/the thickness h1 of the first insulating layer 131)≥(the thermal conductivity of the second insulating layer 132/the thickness h2 of the second insulating layer 132), which may be simply expressed as: TC1/h1≥TC2/h2, where TC1 is the thermal conductivity of the first insulating layer 131, and TC2 is the thermal conductivity of the second insulating layer 132.

In an exemplary application of the board 100, the micro heater 152 is basically to be used to heat the elements above (such as the corresponding pad 128 and the connector thermally coupled thereto). However, considering that the heat generated by the micro heater 152 may also be transferred to the bottom (such as in a direction opposite to the pad 128), the element below (such as, but not limited to, the third circuit layer 143) may be further heated. Therefore, the relationship between the thickness h1 of the first insulating layer 131, the thermal conductivity of the first insulating layer 131, the thickness h2 of the second insulating layer 132, and the thermal conductivity of the second insulating layer 132 may be used, so that the heat transferred to the top of the micro heater 152 is basically no less than the heat transferred to the bottom of the micro heater 152. In this way, the performance and/or applicability of the board 100 can be improved.

It should be noted that the disclosure does not limit the relationship between the thermal conductivity of the first insulating layer 131 and the thermal conductivity of the second insulating layer 132, and/or the relationship between the thickness h1 of the first insulating layer 131 and the thickness h2 of the second insulating layer 132.

In an embodiment, the thermal conductivity of the first insulating layer 131 may be greater than the thermal conductivity of the second insulating layer 132, and the thickness h1 of the first insulating layer 131 may be less than or equal to the thickness h2 of the second insulating layer 132.

In an embodiment, the thermal conductivity of the first insulating layer 131 may be less than or equal to the thermal conductivity of the second insulating layer 132, the thickness h1 of the first insulating layer 131 may be less than or equal to the thickness h2 of the second insulating layer 132, and the thickness h1 of the first insulating layer 131, the thermal conductivity of the first insulating layer 131, the thickness h2 of the second insulating layer 132, and the thermal conductivity of the second insulating layer 132 still have the above relationship.

In an embodiment, the thermal conductivity of the first insulating layer 131 may be greater than or equal to the thermal conductivity of the second insulating layer 132, and the thickness h1 of the first insulating layer 131 may be less than the thickness h2 of the second insulating layer 132.

In an embodiment, the thermal conductivity of the first insulating layer 131 may be greater than or equal to the thermal conductivity of the second insulating layer 132, the thickness h1 of the first insulating layer 131 may be greater than or equal to the thickness h2 of the second insulating layer 132, and the thickness h1 of the first insulating layer 131, the thermal conductivity of the first insulating layer 131, the thickness h2 of the second insulating layer 132, and the thermal conductivity of the second insulating layer 132 still have the above relationship.

Please continue to refer to FIG. 1A and FIG. 1B. In the embodiment, the electronic element 180 may be disposed on the pad 128, and the electronic element 180 may be electrically connected to the pad 128 to form a circuit board 108. In other words, the circuit board 108 may include the board 100 and the electronic element 180.

In the embodiment, the electronic element 180 may include the conductive connector 188. The material of the conductive connector 188 includes, for example, a metal (such as, but not limited to, solder) with a low melting point (that is, less than the melting point of the pad layer 120, the micro heater layer 150, and the first insulating layer 131), and the material of the pad 128 includes, for example, a metal (such as, but not limited to, copper) with a high melting point (that is, higher than the melting point of the conductive connector 188) or an alloy thereof, but the disclosure is not limited thereto.

In the embodiment, the electronic element 180 may be disposed on the corresponding pad 128 through flip-chip bonding, but the disclosure is not limited thereto.

In addition, through the conductive connector 188 of the electronic element 180 and/or the pad 128 corresponding to the electronic element 180, a flow direction D8 of one of the current or the electron flow flowing through the electronic element 180 may be determined when driving the electronic element 180.

In an embodiment, the electronic element 180 may be a light emitting diode, but the disclosure is not limited thereto. In addition, the disclosure does not limit the size or dimensions of the light emitting diode.

In an exemplary application, the circuit board 108 may be a backlight source board or a portion of a backlight source board.

In an exemplary application, the circuit board 108 may be a display board or a portion of a display board.

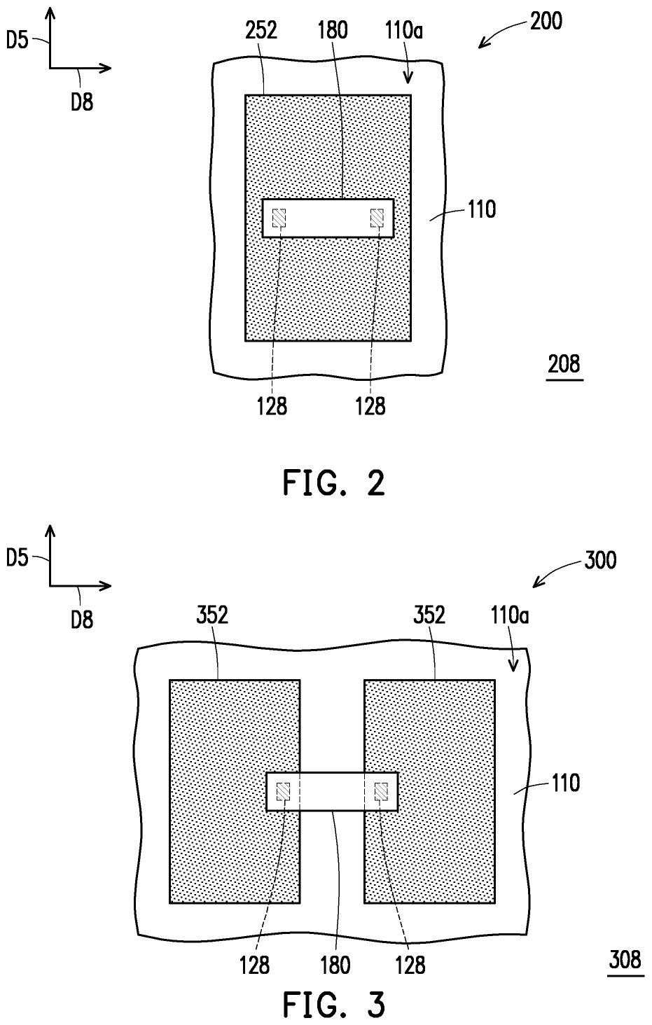

FIG. 2 to FIG. 7 is each a schematic partial top view of a board or a circuit board according to an embodiment of the disclosure. The board or the circuit board in FIG. 2 to FIG. 7 is similar to the board 100 or the circuit board 108 of the above embodiment, and similar components thereof are denoted by the same or similar reference numerals and have similar functions, materials, or uses, so the description is omitted. In addition, for clarity of representation, only boards, micro heaters, pads, and electronic elements are shown in FIG. 2 to FIG. 7. In addition, FIG. 2 to FIG. 7 are only some embodiments, and the disclosure is not limited thereto.

In a board 200 or a circuit board 208 shown in FIG. 2, the flow direction D5 of one of the current or the electron flow flowing through a micro heater 252 is substantially perpendicular to the flow direction D8 of one of the current or the electron flow flowing through the electronic element 180. Moreover, from the top view direction (such as the direction shown in FIG. 2), the electronic element 180 may completely overlap with the micro heater 252.

In a board 300 or a circuit board 308 shown in FIG. 3, the flow direction D5 of one of the current or the electron flow flowing through a micro heater 352 is substantially perpendicular to the flow direction D8 of one of the current or the electron flow flowing through the electronic element 180. Moreover, from the top view direction (such as the direction shown in FIG. 3), the electronic element 180 may partially overlap with the micro heater 352. In addition, one micro heater 352 may be disposed corresponding to one pad 128.

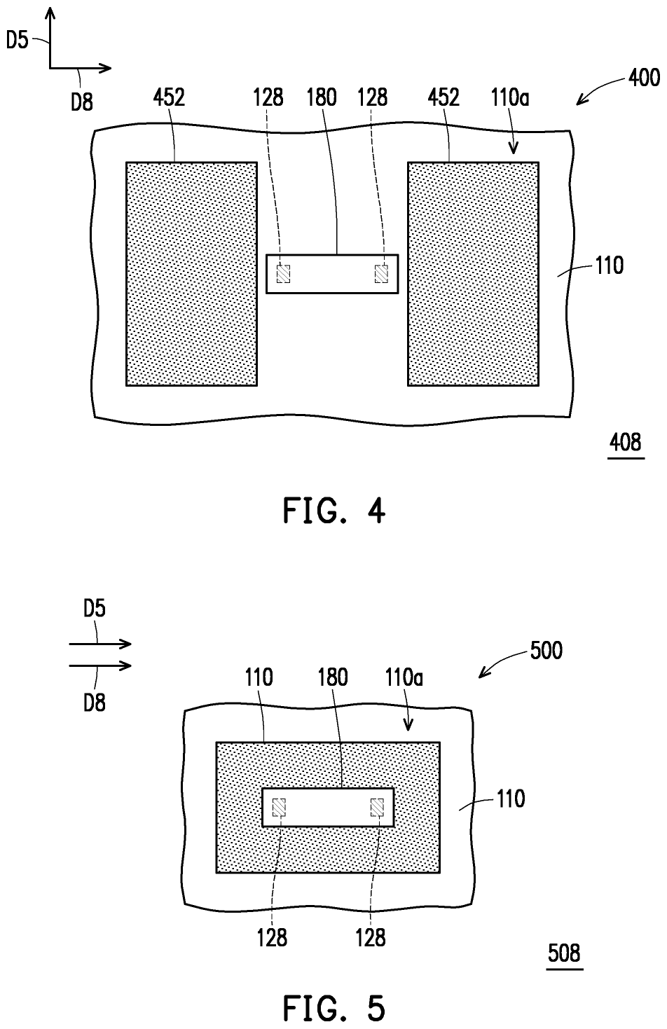

In a board 400 or a circuit board 408 shown in FIG. 4, the flow direction D5 of one of the current or the electron flow flowing through a micro heater 452 is substantially perpendicular to the flow direction D8 of one of the current or the electron flow flowing through the electronic element 180. Moreover, from the top view direction (such as the direction shown in FIG. 4), the electronic element 180 may not overlap with the micro heater 452. In addition, one micro heater 452 may be disposed corresponding to one pad 128.

In a board 500 or a circuit board 508 shown in FIG. 5, the flow direction D5 of one of the current or the electron flow flowing through a micro heater 552 is substantially parallel to the flow direction D8 of one of the current or the electron flow flowing through the electronic element 180. Moreover, from the top view direction (such as the direction shown in FIG. 5), the electronic element 180 may completely overlap with the micro heater 552.

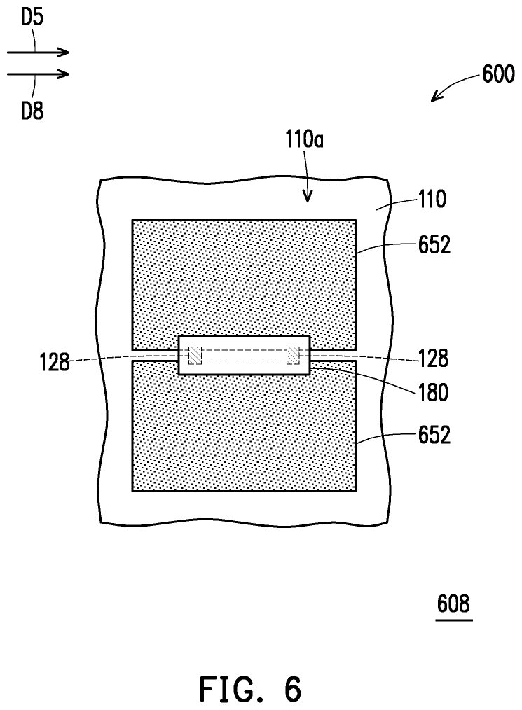

In a board 600 or a circuit board 608 shown in FIG. 6, the flow direction D5 of one of the current or the electron flow flowing through a micro heater 652 is substantially parallel to the flow direction D8 of one of the current or the electron flow flowing through the electronic element 180. Moreover, from the top view direction (such as the direction shown in FIG. 6), the electronic element 180 may partially overlap with the micro heater 652.

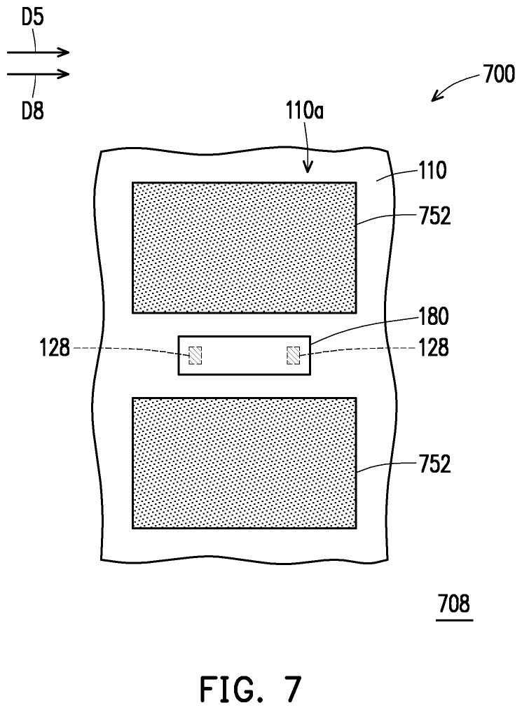

In a board 700 or a circuit board 708 shown in FIG. 7, the flow direction D5 of one of the current or the electron flow flowing through a micro heater 752 is substantially parallel to the flow direction D8 of one of the current or the electron flow flowing through the electronic element 180. In addition, from the top view direction (such as the direction shown in FIG. 7), the electronic element 180 may not overlap with the micro heater 752.

In summary, the disclosure enables the board/the circuit board to be easier to use or to have better performance and/or applicability through the micro heater of the board.

What is claimed is:

1. A board, comprising a laminated structure of:
a pad layer, comprising a pad;
a micro heater layer, comprising a micro heater, wherein the micro heater is disposed corresponding to the pad; and
a first insulating layer, located between the pad layer and the micro heater layer, wherein a resistance value of the micro heater ranges from 10Ω, to 500 Ω.

2. The board according to claim 1, further comprising a second insulating layer, wherein the micro heater layer is located between the second insulating layer and the first insulating layer.

3. The board according to claim 2, wherein the first insulating layer and the second insulating layer conform to a following relationship:
TC1/h1≥TC2/h2,
where h1 is a thickness of the first insulating layer, TC1 is a thermal conductivity of the first insulating layer, h2 is a thickness of the second insulating layer, and TC2 is a thermal conductivity of the second insulating layer.

4. The board according to claim 3, wherein the thermal conductivity of the first insulating layer or the second insulating layer ranges from 1 W·m⁻¹K⁻¹ to 700 W·m⁻¹K⁻¹.

5. The board according to claim 1, wherein the micro heater is disposed corresponding to two of the pads.

6. A circuit board, comprising:
the board according to claim 1, wherein the board further comprises a circuit layer, and the circuit layer is electrically connected to the pad; and
an electronic element, electrically connected onto the pad.

7. The circuit board according to claim 6, wherein the micro heater layer is located between the pad layer and the circuit layer.

8. The circuit board according to claim 6, wherein the circuit layer is located between the pad layer and the micro heater layer.

9. The circuit board according to claim 6, wherein the electronic element is a light emitting diode.

10. The circuit board according to claim 9, wherein the circuit board is a backlight source board.

11. The circuit board according to claim 9, wherein the circuit board is a display board.
